(19) United States
(12) Patent Application Publication
(10) Pub. No.: US 2025/0020785 A1
(43) Pub. Date: Jan. 16, 2025

(54) PHOTONIC ASSEMBLY TUNABLE VIA THE POCKELS EFFECT AND METHOD FOR USE IN FREQUENCY-MODULATED LIDAR

(71) Applicant: Ecole Polytechnique Fédérale de Lausanne (EPFL), Lausanne (CH)

(72) Inventors: Tobias KIPPENBERG, St-Sulpice (CH); Grigorii LIKHACHEV, Chavannes-Renens (CH); Johann RIEMENSBERGER, Sachseln (CH); Viacheslav SNIGIREV, Lausanne (CH)

(73) Assignee: Ecole Polytechnique Fédérale de Lausanne (EPFL), Lausanne (CH)

(21) Appl. No.: 18/712,502

(22) PCT Filed: Nov. 23, 2021
(86) PCT No.: PCT/EP2021/082712

§ 371 Date: May 22, 2024

(51) Int. Cl. G01S 7/4911; G02B 6/12; G02F 1/035

(52) U.S. Cl. CPC G01S 7/4911; G02B 6/12004; G02F 1/035; G02B 2006/12107; G02B 2006/12142

(57) ABSTRACT

A photonic assembly, a laser setup having the photonic assembly and a method for performing frequency-modulated continuous-wave light detection and ranging using the laser setup are disclosed. The photonic assembly has an active photonic chip, a photonic modulator chip, and a tuning arrangement having a modulation element having a thickness of 10 micrometers or less. The active photonic chip and the photonic modulator chip are optically coupled such, that injection radiation at an optical feedback wavelength is generated, which defines at least one optical lasing wavelength at which the optical radiation is emitted by the active photonic chip. The modulation element is arranged such, that an actuation of the modulation element tunes the optical feedback wavelength via the Pockels effect, such, that a tuning of the optical feedback wavelength entails a tuning of the optical lasing wavelength.

### TECHNICAL FIELD

The present invention relates to a photonic assembly, a laser setup comprising said photonic assembly and a method for performing frequency-modulated continuous-wave light detection and ranging using said laser setup.

### PRIOR ART

Chip-scale optical sources emitting optical radiation at a tunable lasing wavelength with a narrow linewidth, i.e. exhibiting very low phase noise, are sought after for many applications ranging from spectroscopy and sensing to metrology and in particular light detection and ranging (LIDAR). The fundamental linewidth of the emitted optical radiation is given by the modified Schawlow-Townes linewidth limit, which dictates that low-loss laser cavities with a high number of photons stored in the cavity allow inherently low phase noise. In addition to quantum noise, thermodynamical noise, such as thermo-refractive noise due to refractive index fluctuations, constitutes another fundamental limit.

To date, it is known in the art that narrow linewidths may be obtained by coupling an optical radiation-emitting chip to an optical cavity or resonator structure, wherein the optical cavity or resonator structure has a resonance linewidth that is much smaller than the gain bandwidth of the light emitting chip.

However, obtaining wavelength tunability over a large wavelength range remains a challenge.

G. Lihachev et al., “Ultralow-noise frequency-agile photonic integrated lasers”, arXiv:2104.02990, 2021, shows self-injection locking (SIL) of an III-V indium phosphide (InP) laser to an ultralow-loss CMOS-compatible silicon nitride (Si₃N₄) optical microresonator monolithically integrated with microelectromechanical systems (MEMS)-based actuators. These actuators exhibit a piezoelectric effect and are actuated by applying a voltage. The actuators are arranged to induce stress on the optical microresonator, such that the resonance wavelength of the optical microresonator shifts upon actuation, thereby causing the lasing wavelength of indium phosphide (InP) laser to shift as well due to the fact that the laser is self-injection locked to the optical microresonator.

Since an actuation via the piezoelectric effect corresponds to a stress optical actuation, the optical tuning range is limited. Furthermore, the tuning speed is limited by internal resonances of the piezoelectrical actuators.

### SUMMARY OF THE INVENTION

In a first aspect, it is an object of the present invention to provide a photonic assembly that enables fast (preferably up to several GHz) and linear wavelength tuning over a large tuning range while being compact and mass-producible.

This object is achieved by a photonic assembly according claim 1. Further embodiments of the invention are laid down in the dependent claims.

A photonic assembly is disclosed, the photonic assembly comprising:
an active photonic chip comprising an optical gain section defining a spectral gain bandwidth, wherein the active photonic chip is configured to emit optical radiation within said spectral gain bandwidth;
a photonic modulator chip comprising a photonic circuit arrangement, wherein the active photonic chip and the photonic modulator chip are optically coupled such, that at least a part of the optical radiation being emitted from the active photonic chip is injected into the photonic circuit arrangement, whereby injection radiation at an optical feedback wavelength is generated, and
wherein the active photonic chip and the photonic modulator chip are further optically coupled such, that at least a part of the injection radiation is reflected back from the photonic circuit arrangement to the active photonic chip such, that the optical feedback wavelength defines at least one optical lasing wavelength at which the optical radiation is emitted by the active photonic chip, and
a tuning arrangement comprising a modulation element exhibiting the Pocket effect, wherein the modulation element is monolithically integrated in the photonic modulator chip and has a thickness of 10 micrometers or less, preferably of 5 micrometers or less, more preferably of 1 micrometer or less, particularly preferably between 200-700 nanometers, with respect to a vertical direction defined by the photonic assembly. For instance, the thickness of the modulation element can be in the range of 100 nanometers to 10 micrometers, such as between 100 nanometers and 5 micrometers, or between 100 nanometers and 1 micrometer.

The modulation element is arranged such, that an actuation of the modulation element tunes the optical feedback wavelength via the Pockels effect, such, that a tuning of the optical feedback wavelength entails a tuning of the optical lasing wavelength.

The terms “optical wavelength” and “optical frequency” are to be considered interchangeable, as an optical wavelength may always be converted into an optical frequency and vice versa by taking into account the properties of the medium in which the optical radiation is propagating. In the context of this disclosure, the term “spectral gain bandwidth” is to be considered equivalent to other terms frequently encountered in the art, such as for instance “optical radiation emission bandwidth” to describe a spectral bandwidth over which radiation may be emitted and/or amplified by the optical gain section of the active photonic chip.

The photonic assembly further defines a horizontal plane perpendicular to the vertical direction. Preferably, the optical radiation propagates parallel to said horizontal plane.

The Pockels effect is an electro-optic effect which changes or induces birefringence in an optical medium induced by an electric field. The Pockels effect describes a linear change of the refractive index of the optical medium as a function of the electric field and is considered to be an instantaneous effect, hence, the Pockels effect offers great potential for fast and linear tuning. The Pockels effect occurs only in crystals that lack inversion symmetry, such as lithium niobate, and in other noncentrosymmetric media such as electric-field poled polymers or glasses.

Here, “monolithically integrated” means that the modulation element stems from a wafer consisting of or comprising a thin film of a material which exhibits the Pockels effect. In particular, said wafer may comprise a thin film of a material exhibiting the Pockels effect arranged on a buried layer, which in turn is arranged on a carrier wafer (e.g. lithium niobate arranged on a silicon carrier wafer with a buried silicon dioxide layer—in this combination known in the art as “lithium niobate-on-insulator (LNOI)”. By integrating the modulation element in the photonic modulator chip as a thin film, i.e. having a thickness of 10 micrometers (μm) or less, preferably 100 nanometers (nm)-10 micrometers (μm), preferably 5 micrometers (μm) or less, preferably 100 nanometers (nm)-5 micrometers (μm), more preferably 1 micrometer (μm) or less, preferably 100 nanometers (nm)-1 micrometer (μm), particularly 200-700 nanometers (nm), in the vertical direction, a very compact photonic assembly is obtained that enables fast and linear wavelength tuning. Depending on the type of embodiments, the modulation element may be Integrated into the photonic modulator chip via direct wafer bonding, transfer printing or direct processing, wherein direct processing may include etching and/or milling as it is known in the state of the art. Preferably, the buried layer and the carrier wafer are removed during integration, e.g. by etching and/or grinding.

The optical feedback wavelength may define the at least one optical lasing wavelength via an injection-locking mechanism caused by the part of the injection radiation that is reflected back from the photonic circuit arrangement to the active photonic chip.

The term “injection-locking” refers to optical injection by means of an optical feedback induced by a resonant Rayleigh scattering on structural inhomogeneities of an external resonator (also often termed “master oscillator”, in this disclosure: the photonic circuit arrangement) to which an optical source (also often termed “a slave oscillator” in this disclosure; the active photonic chip) is locked. The photonic circuit arrangement may exhibit at least one external microcavity mode resonance with a total linewidth κ=κₑₓ+κ_{θ}, where κₑₓ and κ_{κ} stand for an external and an intrinsic decay rate of the at least one external microcavity mode resonance, respectively. The active photonic chip and the photonic modulator chip comprising the photonic circuit arrangement are optically coupled such, that at least a part of the injection radiation generated in the photonic circuit arrangement is reflected back from the photonic circuit arrangement to the active photonic chip. Taking into account Rayleigh scattering with an intermodal coupling rate of y, a coefficient of reflection R may be defined as:

$$\\ R \approx \frac{2 η Γ}{1 + {Γ}^{{}_{} 2}} ,$$

where

$$\\ η = \frac{{κ}_{ex}}{κ} and Γ = \frac{γ}{κ}$$

are dimensionless parameters that represent a coupling efficiency and a mode interaction strength. This reflection launches self-injection locking, which manifests itself in a reduction of a linewidth δω of the optical radiation emitted by the active photonic chip, which reduction may be quantitatively expressed as:

$$\\ δ ω \approx δ {ω}_{free} \frac{{Q}_{L}^{{}_{} 2}}{{Q}^{{}_{} 2}} \frac{1}{16 {R}^{{}_{} 2} ( 1 + {α}_{g}^{{}_{} 2} )} ,$$

where δω_{free} is a free-running (i.e. not injection-locked or “unlocked”) linewidth of the optical radiation emitted by the active photonic chip; Q_{L} and Q=ω/κ are the quality factors of the active photonic chip and of the chosen at least one external microcavity mode, respectively; α_{g} stands for the phase-amplitude coupling factor. Self-injection locking exists within a finite frequency interval around the at least one external microcavity mode resonance, which is called locking bandwidth Δω_{lock}, and can be evaluated by the analytical expression below:

$$\\ Δ {ω}_{lock} \approx R \sqrt{1 + {α}_{g}^{{}_{} 2}} \frac{ω}{{Q}_{L}} .$$

Thus, from the formulae above, it is clear that, in order to obtain a strong linewidth reduction of the optical radiation emitted by the active photonic chip and in order increase the locking bandwidth, a high-Q resonance and strong reflection are preferable.

In some embodiments, the modulation element may be a part of the photonic circuit arrangement, in particular, the injection radiation may be generated within the modulation element exhibiting the Pockels effect. In such embodiments, a major part of the Injection radiation is preferably confined within the modulation element. Having a major part of the injection radiation being confined in the modulation element allows for a particularly efficient tuning of the optical feedback wavelength via the Pockels effect, and hence a particularly efficient tuning of the optical lasing wavelength.

In other embodiments, the photonic circuit arrangement and the modulation element may be configured separately from one another. In this context, “configured separately” means that the photonic circuit arrangement and the modulation element are two different or distinct elements as compared to a single-piece element, for instance. The modulation element may in this case be spatially separated from the photonic circuit arrangement and the photonic circuit arrangement may consist of a different material than the modulation element. In particular, the photonic circuit arrangement may consist of a material that does not exhibit the Pockels effect. In such a case, the photonic circuit arrangement and the modulation element are preferably arranged such, that the injection radiation is mainly confined within the photonic circuit arrangement, but that a minor part of the injection radiation leaks into the modulation element exhibiting the Pockels effect, thus enabling tuning of the optical feedback wavelength via the Pockels effect, such, that a tuning of the optical feedback wavelength entails a tuning of the optical lasing wavelength. An advantage of embodiments where the photonic circuit arrangement and the modulation element are configured separately is that it offers a larger flexibility regarding material and processing choices for the photonic circuit arrangement, since the latter does not need to consist of a material that exhibits the Pockels effect and hence may take advantage of fabrication methods that may not be suitable or lead to less favorable results for materials exhibiting the Pockels effect.

The photonic modulator chip may comprise at least an embedding layer. The photonic circuit arrangement may be at least partially embedded in the embedding layer. In some embodiments, the photonic circuit arrangement may be entirely embedded and thus fully surrounded by the embedding layer. In other embodiments, the photonic circuit arrangement may be in surface contact with the embedding layer. The embedding layer may have a thickness in the vertical direction of 10 μm or less, preferably 6 μm or less, particularly 4 μm.

In particular in cases where the photonic circuit arrangement and the modulation element are configured separately, the modulation element may extend as a modulation layer at least partially along the embedding layer with respect to the horizontal plane being perpendicular to the vertical direction.

The photonic modulator chip may further comprise at least a substrate layer, the embedding layer preferably being arranged on the substrate layer with respect to the vertical direction. In such an arrangement, the embedding layer may act as an insulation layer preventing leakage of the optical radiation into the substrate layer. The substrate layer may have a thickness the vertical direction of 250-925 μm, preferably 250-525 μm.

The photonic circuit arrangement may comprise or consist of silicon nitride and/or silicon. The substrate layer may comprise or consist of silicon (Si). The embedding layer may comprise or consist of silicon dioxide (SiO₂). The modulation element may comprise or consist of lithium niobate (LiNbO₃) and/or lithium tantalate (LiTaO₃) and/or barium titanate (BaTiO₃) or any other material exhibiting the Pockels effect.

In order to enable a precise selection of the optical feedback wavelength, the photonic circuit arrangement may comprise a grating element. The grating element may act as the modulation element and may be in form of a corrugated waveguide acting as a Bragg reflector, which may be actuated using a first actuator and a second actuator, the first actuator and the second actuator preferably being electrodes, extending parallel to one another, wherein the grating element may be arranged between the first actuator and the second actuator. The corrugated waveguide may have a corrugation period Λ that is chosen such that the optical feedback wavelength λ_{f} falls inside the spectral gain bandwidth of the active photonic chip according to λ_{f}=2·n_{eff}·Λ, where n_{eff} is the effective refractive index of the corrugated waveguide. Actuating the actuators, e.g. by applying a voltage, then entails a change of the effective refractive index via the Pockels effect, which entails a tuning of the optical feedback wavelength λₜ and the optical lasing wavelength λ_{L}.

The photonic circuit arrangement may comprise at least one coupling waveguide and at least one optical microresonator, wherein the at least one optical microresonator preferably has a circular shape or a race-track shape and/or has a rectangular or a trapezoidal cross-section.

In order for the at least one optical lasing wavelength to have a narrow linewidth, the at least one optical microresonator may have a quality factor preferably larger than 10⁶, wherein the quality factor is defined as the ratio of the resonance frequency and the full width at half-maximum (FWHM) bandwidth of the resonance.

Preferably, the at least one optical microresonator and the least one coupling waveguide are arranged in a common plane, and the least one optical coupling waveguide is preferably configured to guide the optical radiation emitted by the active photonic chip and to couple a portion of said optical radiation into the at least one optical microresonator, thereby generating the injection radiation at the feedback wavelength. Said common plane preferably extends parallel to the horizontal plane mentioned above. In order to be able to guide and/or store the optical radiation emitted by the active photonic chip, the at least one optical coupling waveguide and the at least one optical microresonator ideally exhibit cross-sectional dimensions which are adapted to a wavelength range at least partially overlapping with the spectral bandwidth of the optical gain section. The cross-sectional dimensions may be chosen such, that only a fundamental transverse-electric (TE) spatial mode (i.e. the electric field amplitude spatial distribution) is supported or such that higher-order TE spatial modes are also supported. Optimizing the cross-sectional dimensions may be done by methods known in the art, such as using finite-element-method simulations or finite-difference time domain simulations. The goal of optimization may be to maximize the fraction of the optical radiation that is confined in the modulation element while simultaneously minimizing optical propagation losses due to bending and/or absorption.

The at least one optical microresonator itself may be the modulation element exhibiting the Pockels effect. That is, the optical microresonator and the modulation element may be provided as a single component, i.e., constitute a single-piece element. In this case, the at least one optical microresonator preferably comprises or consists of lithium niobate and/or lithium tantalite and/or barium titanate. To enable optimum coupling between the at least one optical microresonator and the at least one optical coupling waveguide, the latter preferably also comprises or consists of lithium niobate and/or lithium tantalite and/or barium titanatein such a case.

To minimize coupling losses between the active photonic chip and the photonic modulator chip, the coupling waveguide may comprise an input section preferably having an inverse taper or a horn taper.

To achieve a compact setup and reduce the risk of misalignments over time, the active photonic chip may be butt-coupled to said input section, the term “butt-coupled” meaning in this case that the active photonic chip is arranged sufficiently close to the photonic modulator chip that the optical radiation may be coupled from the active chip to the photonic modulator chip and vice versa without needing any additional components.

The Input section may have an end that is arranged at a distance of a facet of the photonic modulator chip, through which facet the optical radiation is being coupled from the active chip to the photonic modulator chip and/or vice versa, the distance preferably being less than 3 μm. Such an arrangement is particularly advantageous in case the facet material, which may be the material of the embedding layer, e.g. SiO₂, exhibits an optical impedance (i.e. a refractive index) which is more suitable for coupling with the active chip than the optical impedance of the material of the input section of the optical coupling waveguide, e.g. Si₃N₄.

In cases where the modulation element is configured as a modulation layer arranged on the embedding layer, a portion of the embedding layer may not be covered by the modulation layer. Preferably, the input section of the coupling waveguide is then arranged within said portion of the embedding layer. Such an arrangement may further help to minimize the coupling losses.

The at least one optical microresonator may have multiple resonance wavelengths spaced by a free-spectral range, wherein the free-spectral range is larger than the spectral gain bandwidth of the active photonic chip. As it is known in the art, the free-spectral range is inversely proportional to a circumference of the at least one optical microresonator. Hence, depending on the spectral gain bandwidth of the active photonic chip, the circumference of the at least one optical microresonator may be chosen by design such that the free-spectral range is larger than the spectral gain bandwidth of the active photonic chip. Provided that the at least one optical microresonator is configured such that one of the multiple resonance wavelengths lies within the spectral gain bandwidth of the active photonic chip, such an arrangement enables to create a preferable situation where the optical radiation is emitted only at one optical lasing wavelength. In order to tune the resonance wavelength into the spectral gain bandwidth of the active photonic chip in case it lies outside said gain bandwidth or to optimize coupling, the modulation element may be actuated, or an additional actuator may be used, such as a heater or a piezoelectric element, which additional actuator may be arranged below, on, or adjacent to the at least one optical microresonator.

The photonic circuit arrangement may comprise at least two optical microresonators with differing free-spectral ranges, wherein each of the free-spectral ranges is smaller than the spectral gain bandwidth of the active photonic chip. The at least two optical microresonators may be configured to share at least one common resonance wavelength, and the at least two optical microresonators may be arranged such, that the optical feedback wavelength corresponds to the at least one common resonance wavelength. In order for the at least two optical microresonators to share at least one common resonance wavelength, at least one of the at least two microresonator may be tuned by using the modulation element or by means of a heating element or a piezoelectric element to shift at least one resonance of said tuned optical microresonator until an overlap with at least one resonance of at least one of the other optical microresonators is achieved. In order to couple the optical radiation at the atleast one common resonance wavelength from one optical microresonator another, the photonic circuit arrangement may further comprise several optical coupling waveguides.

Preferably, the coupling waveguides are arranged such that the optical radiation at the at least once common resonance wavelength is transmitted from a first coupling waveguide through each optical microresonator to a last coupling waveguide and that transmission of optical radiation at other wavelengths than the at least one common resonance wavelength to the last coupling waveguide is strongly or completely suppressed. Such an arrangement creates a so-called “Verniere”-filter, i.e. a filter which suppresses resonance wavelengths that are not shared by the at least two optical microresonators. Such a Vernier-filter may have effective free-spectral range which is larger than the free-spectral ranges of each of the at least two optical microresonators. Preferably, the effective free-spectral range of the Vernier filter exceeds the spectral gain bandwidth of the active photonic chip. By choosing said effective free-spectral such, that only one optical feedback wavelength is situated within the spectral gain bandwidth of the optical gain section of the active photonic chip, this Vernier-filter may then be used to force the active photonic chip to emit optical radiation at only one optical lasing wavelength.

The photonic circuit arrangement may further comprise a waveguide section configured to form a mirror that reflects a portion of the injection radiation exiting the optical microresonator after having propagated in the optical microresonator in a first direction back into the at least one optical microresonator in a second direction opposite to the first direction. This waveguide section may be loop-shaped or exhibit any other suitable form. Preferably, a loop-shaped waveguide section may have ends which are connected to a waveguide splitter such as a multimode-interference splitter or a waveguide y-splitter.

The tuning arrangement may comprise at least a first actuation element and a second actuation element, wherein the first actuation element and the second actuation element are configured to actuate the modulation element, and wherein the first actuation element and the second actuation element preferably are electrodes comprising or consisting of tungsten and/or niobium. In order to enable a build-up of an electric field between the first and the second actuation element, the first actuation element and the second actuation element preferably are arranged at a distance from one another. Preferably, said distance is preferably in the range of 3-12 μm.

The first actuation element and/or the second actuation element may be arranged at an offset from the at least one optical microresonator with respect to a radial direction and/or with respect to the vertical direction running perpendicularly to the radial direction. Said vertical direction preferably corresponds to the vertical direction of the photonic assembly mentioned above. If the photonic circuit arrangement comprises several optical microresonators, each optical microresonator may have a first actuation element and a second actuation element associated with it.

The at least one optical microresonator may define an inner circumference and an outer circumference, wherein the first actuation element extends along the inner circumference of the at least one optical microresonator over a length that amounts to half of a length of the inner circumference of the at least one optical microresonator or less, and wherein the second actuation element extends along the outer circumference of the at least one optical microresonator over a length that amounts to half of a length of the outer circumference of the at least one optical microresonator or less. The length over which the actuation elements extend may influence tuning the optical feedback wavelength. In particular, the tuning performance may deteriorate if the actuation elements extend over more than half the inner and/or the outer circumference respectively.

The active photonic chip may be a distributed-feedback laser diode or a Fabry-Perot laser diode or a reflective semiconductor amplifier or any other suitable chip-scale light source.

In a second aspect, the present invention provides a laser setup comprising: the photonic assembly as described above:
a tunable source driver configured to drive the active photonic chip, and a tunable voltage source configured to provide a tunable voltage to the tuning arrangement.

In order to characterize the performance of the photonic assembly, the laser setup may further comprise a diagnostics setup.

Any statements made herein with regard to the photonic assembly per se likewise apply to the laser setup comprising the photonic assembly and vice versa.

In a third aspect, the present invention provides a method for performing frequency-modulated continuous-wave (FMCW) light detection and ranging (LIDAR) using the laser setup as described above, wherein the setup further comprises an optical splitter and a detector and wherein the method comprises:
tuning the optical lasing wavelength of the optical radiation by applying a voltage generated by the tunable voltage source to the tuning arrangement;
splitting off a first portion of the optical radiation to act as local oscillator radiation using the optical splitter;
sending a second portion of the optical radiation being split of by the optical splitter and acting as signal radiation towards a target which at least partially reflects said signal radiation;
obtaining a detection signal by detecting a superposition of the reflected signal radiation and the local oscillator radiation by the detector, and
retrieving a ranging parameter from the detection signal.

Using a laser setup according to the present invention provides the advantage that no additional processing is needed to linearize the wavelength excursion of the optical lasing wavelength to enable FMCW LIDAR experiments, since the inherent nonlinearity is sufficiently low, i.e. a linear voltage ramp leads to a nearly linear wavelength excursion. To calibrate the wavelength excursions, a fraction of the optical radiation exiting the photonic modulator chip may be split off before or after the optical splitter to act as reference radiation and may be sent to a reference Mach-Zehnder interferometer (MZI). The length of the MZI may be determined by an independent measurement involving a tunable diode laser scan calibrated by a frequency comb. The voltage generated by the tunable voltage source is preferably a triangular voltage ramp, which is amplified by a high-voltage amplifier. The detection signal may be obtained by detecting a superposition of the reflected signal radiation and the local oscillator radiation together with a superposition of the local oscillator radiation and the reference radiation on the detector, wherein the detector preferably is a balanced photodetector. Preferably, the ranging parameter retrieved from the detection signal is a distance value.

### BRIEF DESCRIPTION OF THE DRAWINGS

Preferred embodiments of the invention are described in the following with reference to the drawings, which are for the purpose of illustrating the present preferred embodiments of the invention and not for the purpose of limiting the same. In the drawings,

FIG. 1 schematically shows a laser setup comprising a photonic assembly according to a first embodiment of the present invention:

FIG. 2 shows a sectional view of sectional plane A-A marked in FIG. 1;

FIG. 3 shows an enlarged view of the excerpt E marked in FIG. 2;

FIG. 4 shows a photographic image of the embodiment schematically shown in FIGS. 1 to 3;

FIG. 5a-g show experimental data obtained with a photonic assembly according to the first embodiment of the present invention as illustrated in FIG. 1-4;

FIG. 6a-e show further experimental data obtained with a photonic assembly according to the first embodiment of the present invention as illustrated in FIG. 1-4;

FIG. 7 shows a scanning-electron microscopy (SEM) image corresponding to the schematic sectional view of the first embodiment illustrated in FIG. 2:

FIG. 8 shows a preferred fabrication process for a photonic modulator chip;

FIG. 9a,b show enlarged excerpt of a sectional view of a photonic modulator chip configuration where an optical microresonator is part of the modulation element;

FIG. 10 schematically shows a photonic assembly with a photonic circuit arrangement according to a second embodiment of the present invention;

FIG. 11a-c schematically illustrate a Vernier-filler effect, which may be achieved with the photonic circuit arrangement shown in FIG. 10;

FIG. 12 schematically shows a photonic assembly according to a third embodiment of the present invention;

FIG. 13 schematically shows a photonic assembly 1 according to a forth embodiment of the present invention;

FIG. 14 schematically shows a photonic assembly 1 according to a fifth embodiment of the present invention;

FIG. 15 schematically illustrates an implementation of the laser setup shown in FIG. 1 frequency-modulated continuous-wave (FMCW) light detection and ranging (LIDAR);

FIG. 16a-c show experimental measurements obtained using the implementation shown in FIG. 15.

### DESCRIPTION OF PREFERRED EMBODIMENTS

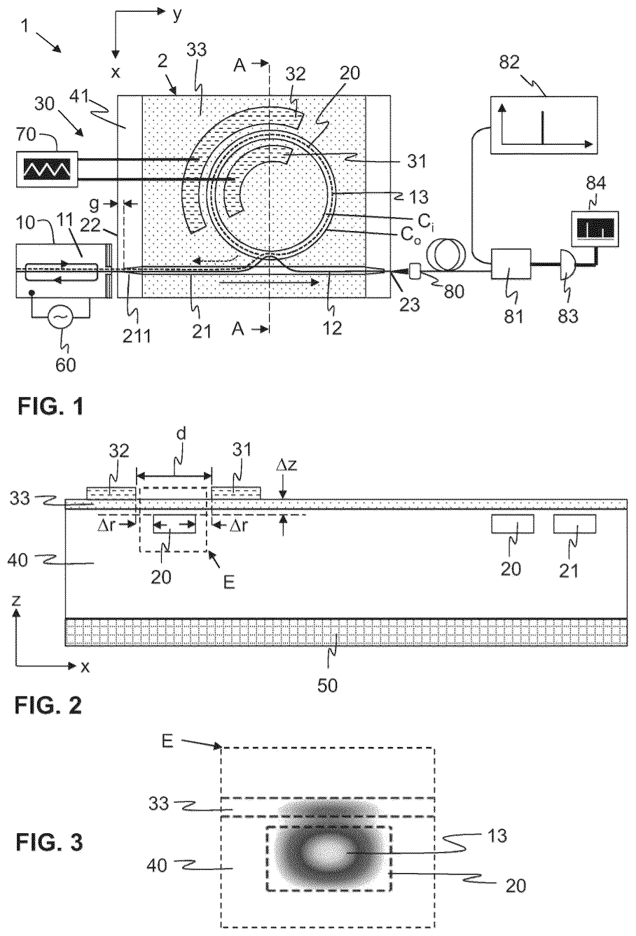

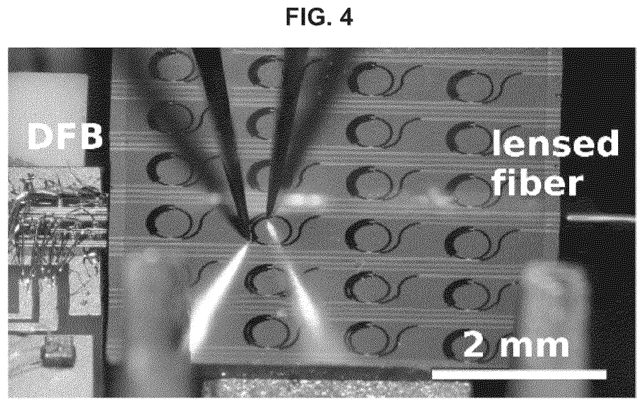

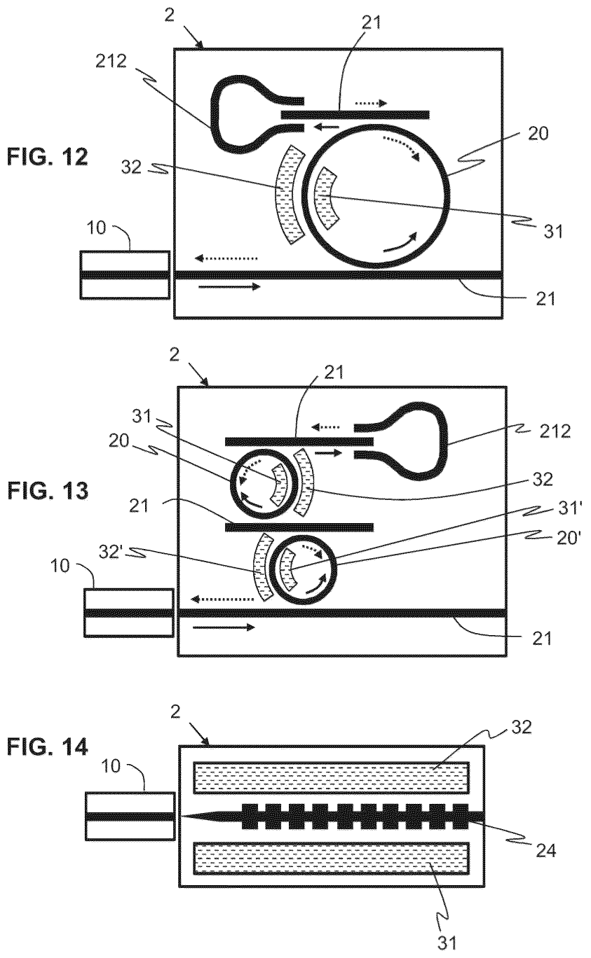

FIG. 1 schematically shows a laser setup (not to scale) comprising a photonic assembly 1 according to a first embodiment of the present invention. The photonic assembly 1 comprises an active photonic chip 10 with an optical gain section 11. The active photonic chip 10 is configured to emit optical radiation 12. The laser setup comprises a tunable source driver 60 configured to drive the active photonic chip. The photonic assembly 1 further comprises a photonic modulator chip 2 comprising a photonic circuit arrangement. In this particular embodiment, the photonic circuit arrangement comprises an optical microresonator 20 having a circular shape and an optical coupling waveguide 21. The optical coupling waveguide 21 is configured to guide the optical radiation 12 emitted by the active photonic chip and to couple a portion of said optical radiation 12 into the optical microresonator 20, thereby generating injection radiation 13 at a feedback wavelength λₜ. The optical coupling waveguide 21 drawn schematically in FIG. 1 extends along a straight line, it may however also comprise curved portions as shown in a photographic image in FIG. 4. The active photonic chip 10 and the photonic modulator chip 2 are further optically coupled such that at least a part of the injection radiation 13 is reflected back from the photonic circuit arrangement to the active photonic chip 10 such that the optical feedback wavelength λ_{f} defines at least one optical lasing wavelength λₜ at which the optical radiation 12 is emitted by the active photonic chip 10 (see also FIGS. 12a-d). To minimize coupling losses, the coupling waveguide 21 comprises an input section 211 having an inverse taper, i.e. a cross-section which gets smaller towards an end of the input section 211. The end of the input section is furthermore arranged at a distance g of a facet 22 of the photonic modulator chip 2, through which facet 22 the optical radiation is being coupled from the active chip 10 to the photonic modulator chip 2 and/or vice versa. In this embodiment, the active photonic chip 10 is butt-coupled to said input section 211, i.e. the active photonic chip 10 is arranged sufficiently close to the photonic modulator chip 2 such that the optical radiation 12 may be coupled from the active chip 10 to the photonic modulator chip without needing any additional components.

The photonic assembly 1 further comprises a tuning arrangement 30 comprising a modulation element 33 exhibiting the Pockels effect. The modulation element is arranged such, that an actuation of the modulation element 33 tunes the optical feedback wavelength λ_{f} via the electro-optic effect, such, that a tuning of the optical feedback wavelength λ_{f} entails a tuning of the optical lasing wavelength λ_{f}. The arrangement of the modulation element 33 in this particular embodiment is further illustrated in FIG. 2, which shows a sectional view of sectional plane A-A marked in FIG. 1. As can be seen in FIG. 2, the photonic modulator chip comprises an embedding layer 40, wherein the optical microresonator 20 and the coupling waveguide 21 are in this case fully embedded in the embedding layer 40. The modulation element 33 extends here as a modulation layer along the embedding layer 40 with respect to a horizontal plane (x-y-plane in FIG. 1) perpendicular to the vertical direction z and has a thickness in the vertical direction z of 10 micrometers or less, preferably 1 micrometer or less, particularly 200-700 nm. As shown in FIG. 1, a portion 41 of the embedding layer 40 is not covered by the modulation layer 33 and the input section 211 of the coupling waveguide 21 is arranged within said portion of the embedding layer 41. The photonic modulator chip 2 further comprises a substrate layer 50, the embedding layer being arranged on the substrate layer 50 with respect to the vertical direction z. Here, the tuning arrangement 30 comprises a first actuation element 31 and a second actuation element 32, wherein the first actuation element 31 and the second actuation element are electrodes consisting of tungsten, which are configured to actuate the modulation layer 33. The first actuation element 31 and the second actuation element 32 preferably are arranged at a distance d from one another. The first actuation element 31 and the second actuation element 32 are arranged at an offset or from the at least one optical microresonator with respect to a radial direction and at an offset Δz with respect to the vertical direction z running perpendicularly to the radial direction. Here, the radial direction lies in a plane parallel to the modulation layer 33. The offset Δr with respect to the radial direction preferably amounts to 3-12 μm.

The offset Δz with respect to the vertical direction preferably amounts to 1 μm or less. The optical microresonator 20 defines an inner circumference Ci and an outer circumference Co. To enable optimum modulation, the first actuation element 31 extends along the inner circumference Ci of the optical microresonator 20 over a length that amounts to less than half of a length of the inner circumference Ci of the at least one optical microresonator 20, while the second actuation element 32 extends along the outer circumference Co of the optical microresonator 20 over a length that amounts to less than half of a length of the outer circumference Co of the optical microresonator 20. Preferably the first actuation element 31 and the second actuation element 32 each have a thickness along the z-direction of 100 nm-10 μm.

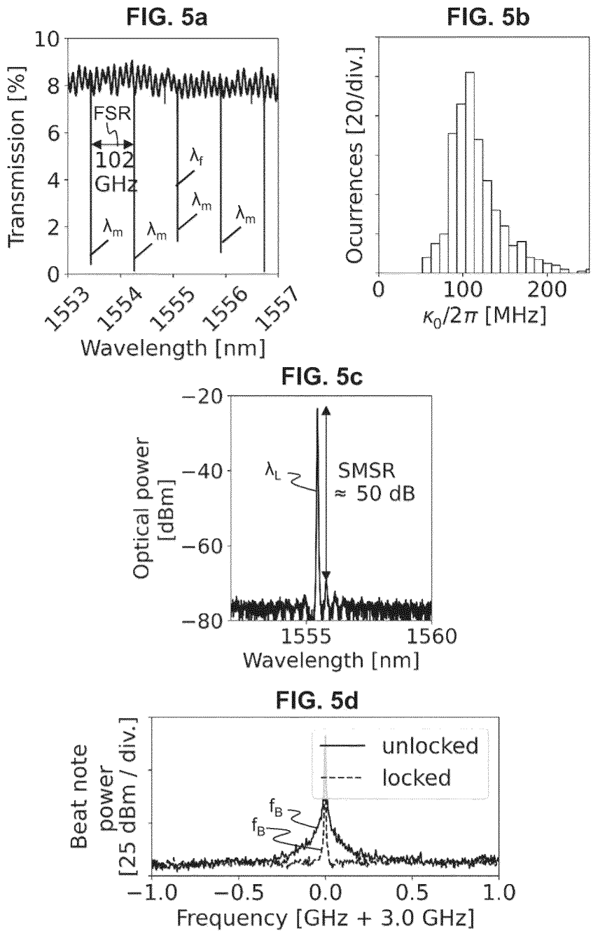

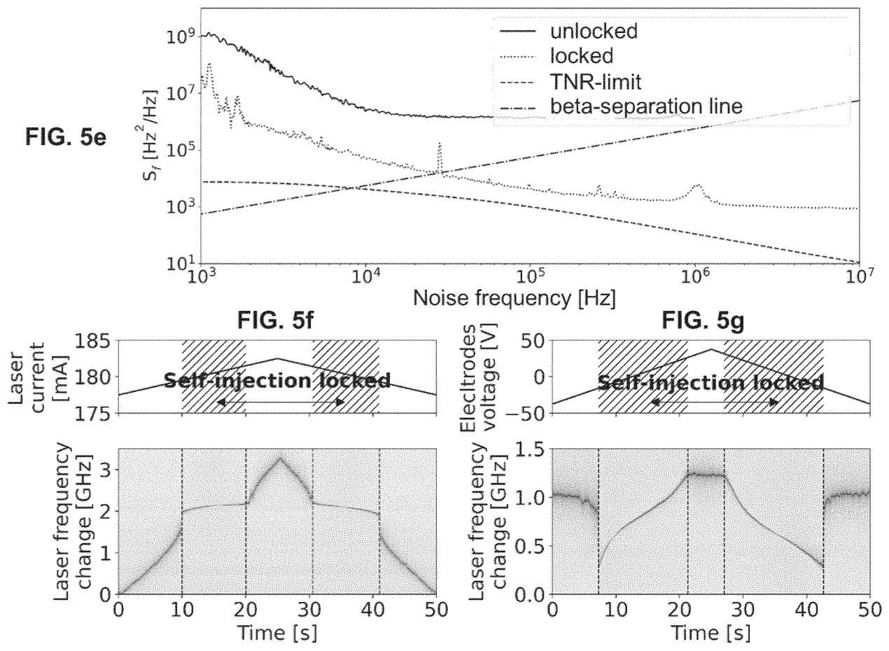

The laser setup further comprises a tunable source driver 60 configured to drive the active photonic chip, and a tunable voltage source 70 configured to provide a tunable voltage to the tuning arrangement 30. The tunable voltage source 70 may comprise an arbitrary waveform generated connected to a high-voltage amplifier. FIG. 1 further shows a diagnostics setup comprising a lensed fiber 80 arranged at an output 23 of the photonic circuit arrangement to collect the optical radiation 12 exiting the photonic modulator chip 2. The lensed fiber 80 leads to a 50:50 beam splitter/beam combiner 81, in which the optical radiation 12 exiting the photonic modulator chip 2 is superposed with reference optical radiation emitted by a reference continuous-wave laser source 82. Using a photodiode 83 arranged after the 50:50 beam splitter/beam combiner 81 and a radiofrequency analyzer 84, a heterodyne beat-note ft resulting from said superposition may be detected and analyzed (see also FIG. 5d).

FIG. 3 shows an enlarged view of the excerpt E marked in FIG. 2. A simulation of a hybrid transverse-electric (TE) electric field amplitude spatial distribution of the injection radiation 13 propagating in the optical microresonator 20 is shown, revealing in this case how a major part of the optical radiation 12 is confined within the optical microresonator, while a minor part of the optical radiation 12 leaks through the embedding layer into the modulation layer 33, where it may experience modulation due to the Pockels effect when the modulation layer 33 is actuated via the electrodes 31,32.

FIG. 4 shows a photographic image of the embodiment schematically shown in FIGS. 1 to 3, wherein the active photonic chip is a distributed-feedback (DFB) laser diode and wherein the tuning arrangement 30 comprises needle probes via which a voltage is being applied to the electrodes and a lensed fiber collecting the optical radiation at an output of the photonic modulator chip. As can be seen in FIG. 4, the photonic modulator chip 2 may comprise a multitude of identical optical microresonators 20 and optical waveguides 21 that have been fabricated in the same fabrication run to enable a user to pick the ones which exhibit the least fabrication errors.

FIGS. 5a-g show experimental data obtained with a photonic assembly according to the first embodiment of the present invention as illustrated in FIG. 1-4, i.e. where active photonic chip is a DFB laser diode. The optical microresonator 20 has multiple resonance wavelengths λₘ spaced by a free-spectral range FSR, wherein the FSR in this first embodiment is larger than the spectral gain bandwidth of the DFB laser diode.

FIG. 5a shows a transmission trace of the optical microresonator 20, where the multiple resonance wavelengths λₘ are visible. In this case, the optical microresonator 20 has an FSR of 102-GHz.

FIG. 5b shows a histogram showing the distribution of resonance linewidths of a selection of 593 resonances of said optical microresonator with a median linewidth value of 100 MHz or, equivalently, a quality factor of 1.9×10⁶.

FIG. 5c shows an optical emission spectrum of the free-running DFB laser diode.

FIG. 5d shows a heterodyne beat-note f_{B} obtained by superposing the optical radiation 12 with reference optical radiation emitted by the reference continuous-wave laser source 82 (for these measurements: and external cavity diode laser (Toptica CTL)) in a case where no feedback to the active photonic chip occurs (“unlocked”, solid line) compared to a case where self-injection locking occurs (“locked”, dashed line).

FIG. 5e shows frequency noise spectra obtained by measuring the frequency noise of the heterodyne beat-note f₈ shown in FIG. 5d for the case where no feedback to the active photonic chip occurs (“unlocked”, solid line) compared to the case where self-injection locking occurs (“locked”, dotted line). The heterodyne beat-note f_{B} was detected on a photodiode, wherein the electrical output of the photodiode was then sent to an electrical spectrum analyser (Rohde & Schwarz FSW43). The recorded data for the in-phase and quadrature components of the heterodyne beat-note f_{B} were processed by Welch's method (P. Welch, “The use of fast Fourier transform for the estimation of power spectra: A method based on time averaging over short, modified periodograms.” IEEE Transactions on Audio and Electroacoustics, vol, 15, no. 2, 70-73. June 1967, DOI: 10.1109/TAU.1967.1161901) to retrieve the phase noise power spectral density S_{ϕ}, which was then converted to the frequency noise power spectral density S_{f} by means of the expression S_{f}=f²·S_{ϕ}, where f is the noise frequency. Self-injection locking causes a drop of the frequency noise power spectral density S_{f} level of approximately 20 dB on average across the span of noise frequencies shown in FIG. 5e. To calculate the linewidth of the optical lasing wavelength/frequency given the frequency noise power spectral density S_{f}, the procedure explained by G. Di Domenico et al., “Simple approach to the relation between laser frequency noise and laser line shape,” Appl. Opt. 49, 4801-4807, (2010), DOI:10.1364/AO.49.004801 is applied: one integrates the frequency noise power spectral density S_{f} from an initial noise frequency value corresponding to an inverse observation time to a point of intersection between the frequency noise power spectral density S_{f} and the beta-separation line, wherein the beta-separation line is given by the formula: S_{f}(f)=8 ln 2·f/π² and is shown as a dashed-dotted line in FIG. 5e. The evaluated area under the curve A is then used to obtain a full-width-at-half-maximum (FWHM) measure of the linewidth using the following expression: FWHM=\sqrt{8 ln 2·A}, The frequency noise power spectral density S_{f} obtained when the DFB laser is self-injection locked to the 102-GHz optical microresonator shows an intersection point with the beta-line at a noise frequency f of approximately 30 kHz, which then results in a linewidth of 56 kHz at 0.1 ms observation time, 262 kHz at 1 ms observation time, and 1.1 MHz at 100 ms observation time. The frequency noise power spectral density S_{f} reaches a horizontal plateau of 103 Hz²/Hz at a noise frequency of 3 MHz, which corresponds to an intrinsic linewidth of 3.14 kHz.

Furthermore, the simulated thermo-refractive noise (TRN) limit (dashed line) is shown for reference. The TRN-limit was simulated following the approach described by G. Huang et al., “Thermorefractive noise in silicon-nitride microresonators,” Physical Review A 99, 061801, 2019, DOI: 10.1103/PhysRevA.99.061801. The dimensionless value of the frequency fluctuation of a resonator δω/ω were chosen as the fluctuation observable; temperature fluctuation δθ as a generalized coordinate; and entropy as the generalized force (that is conjugated with temperature). As this generalized force depends on the normalized optical mode field distribution \vec{e}(\vec{r}), it was simulated for the selected 102-GHz-FSR optical microresonator geometry by means of a finite-element-method (FEM) waveguide eigenfrequency solver. Next, the numeric solution θ̅(\hat{r},ω) to the heat transfer problem in the frequency domain was obtained using the normalized optical mode field distribution \vec{e}(\vec{r}) simulated on the previous step as the parameter for the heat source for a finite number of frequency values belonging to a preset range. After that, the dissipated energy W_{dlss} was evaluated and substituted into the expression for the resonator frequency fluctuations (one-sided) power spectral density S_{δω/w}.

FIG. 5f shows a time-frequency map of the heterodyne beat-note reflecting a tuning of the optical lasing wavelength of the DFB laser for a linear modulation of a laser current applied to the DFB laser diode via the tunable source driver 60, wherein the feedback wavelength λ_{f} is kept constant during measurement of the time-frequency map shown in FIG. 5f. The dashed areas mark laser current ranges for which no significant frequency/wavelength change of the optical lasing wavelength occurs, i.e. the current ranges for which the optical lasing wavelength λ_{L} is defined by, in this case self-injection locked to, the feedback wavelength Δ_{L}.

FIG. 5g shows a time-frequency map visualizing the limits of the self-injection locking bandwidth. For the measurement shown in FIG. 5g, the laser current applied to the DFB laser diode via the tunable source driver 60 remained constant, wherein said constant laser current was chosen such that optical lasing wavelength h was sufficiently close to one the optical microresonator resonances wavelengths λₘ to enable self-injection locking. A voltage was then applied to the electrodes 31,32 in form of a linear triangular ramp versus time using the tunable voltage source 70, leading to a spectral tuning of the optical feedback wavelength λ_{f} via the Pockels effect. The voltage ranges over which the tuning of the voltage entails a tuning of the optical lasing wavelength λ_{L}. i.e. the voltage range over which the optical lasing wavelength λ_{L} is effectively self-injection locked, is shown as dashed areas. The measurement suggests that self-Injection locking was achieved within a tuning range of around 1 GHz, wherein linear tuning was observed within a range of 0.5 GHz.

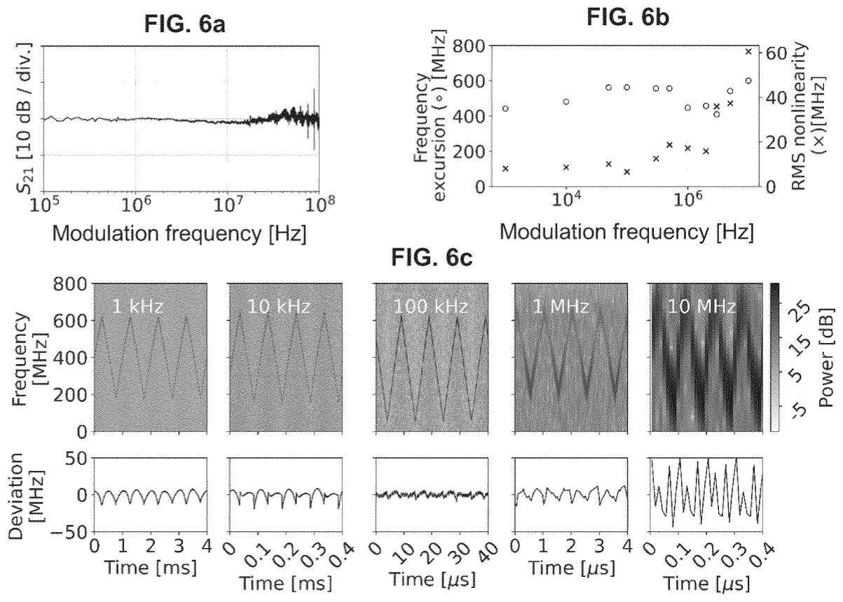

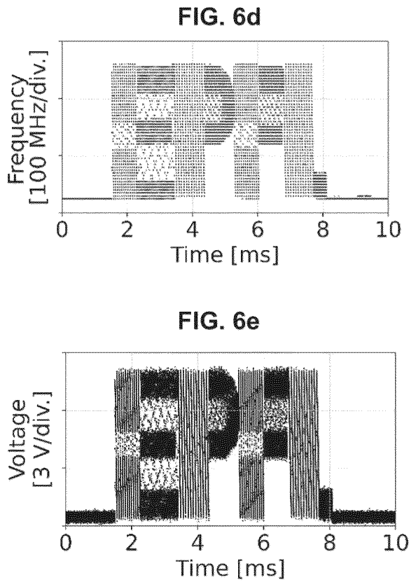

An important advantage of the present invention is that it enables a flat modulation response function over a large modulation frequency range. FIG. 6a shows a measured modulation transfer function that was obtained while actuating the tungsten electrodes 31,32 in the embodiment described above with a sweep of different modulation frequencies using the tunable voltage source 70. As can be seen in FIG. 6a, the measured modulation transfer function is flat up to a modulation frequency of 100 MHz. The flat modulation transfer function implies minimal nonlinearity, i.e. when applying a linear voltage ramp to the electrodes, the optical lasing frequency shifts essentially linearly as well. In order to demonstrate the frequency agility experimentally, the DFB laser was self-injection locked to one of the 102-GHz-FSR optical microresonator resonances, and the alternating voltage signals in the form of triangular ramps with 25 V of peak-to-peak voltage and various modulation frequencies ranging from 1 kHz to 10 MHz were sequentially applied to the electrodes 31,32. Via the Pockels effect, the voltage modulates the refractive index of modulation layer 33, which in this embodiment consists of lithium niobate and, consequently, shifts the optical feedback wavelength λ_{f} to which the DFB laser diode is self-Injection locked. To reveal a time-varying wavelength/frequency change, the heterodyne beat-note fa was obtained by superposing the optical radiation 12 with reference optical radiation emitted by the reference continuous-wave laser source 82 on a fast photodiode. The heterodyne beat note was then sampled with an oscilloscope.

The summary of these measurements is given in FIG. 6b, where the values for the frequency excursion and the deviation of the actually generated frequency modulation profile from the perfect linear ramp (termed “root mean square (RMS) nonlinearity” in FIG. 6b) are presented. The deviation was calculated by fitting the experimental data with the least squares fitting method to obtain a fit and then computing the difference between the fit and the actual data. The values for the frequency excursion on average remain on the same level of roughly 500 MHz with fluctuations on the order of 10's of MHz, whereas the RMS nonlinearity tends to increase with an increase in modulation frequency. The minimum nonlinearity of approximately 1% of the frequency excursion was observed at a modulation frequency of 100 kHz.

A selection of data for characteristic modulation frequency values (1 kHz, 10 kHz, 100 kHz, 1 MHz. 10 MHz) is given in FIG. 6c. The upper row in FIG. 6c shows the heterodyne beat-note time-frequency maps obtained by applying short-time Fourier transform to the heterodyne beat-note oscillograms recorded with the fast photodiode. The lower row in FIG. 6c shows the difference between the experimental data and their least squares fit. Although modulation with a linear ramp is preferred for many practical applications, in principle, the optical lasing wavelength λ_{L}/frequency can be modulated in an arbitrarily complicated manner with a high tuning rate. To illustrate this, an arbitrary waveform generator programmed to reproduce the logos of the EPFL university was used as the tunable voltage source 70. FIG. 6d shows a time-frequency plot showing rapid tuning of the heterodyne beat-note fa caused by rapid tuning of the optical lasing wavelength λ_{L}/frequency in a pattern resembling the EPFL university logo at a maximum tuning rate of 450 THz/s with a repetition frequency of 76 Hz. FIG. 6e shows the same EPFL university logo in a time-voltage plot.

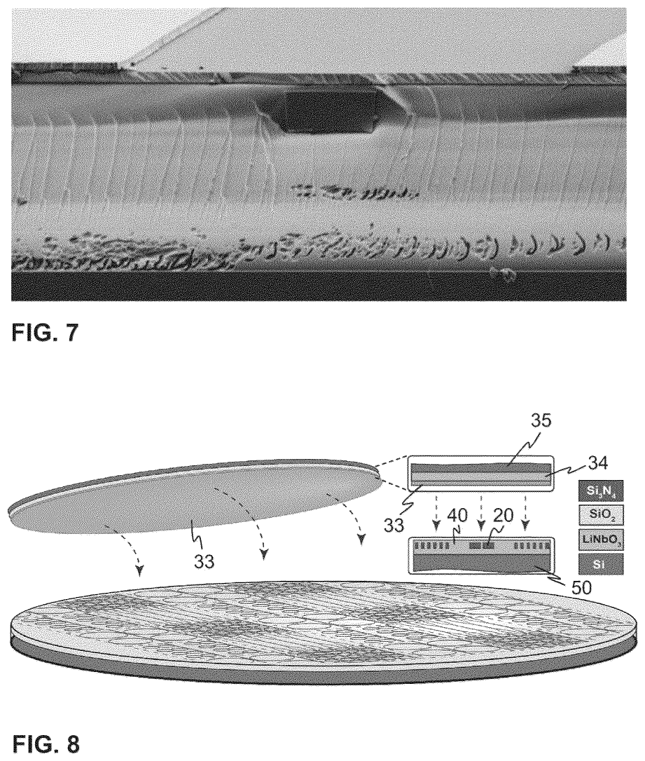

FIG. 7 shows a scanning-electron microscopy (SEM) image corresponding to the schematic sectional view of the first embodiment illustrated in FIG. 2.

In the embodiment shown in FIG. 4 and FIG. 7, the optical microresonator 20 and the optical waveguide 21 both consist of silicon nitride (Si₃N₄), the substrate layer 50 consists of silicon (Si), the embedding layer 40 consists of silicon dioxide (SiO₂), and the modulation layer 33 consists of lithium niobate (LiNbO₃). FIG. 8 depicts a preferred fabrication process using heterogeneous integration based on wafer bonding for such a material combination: The process starts with the fabrication of a patterned and planarized Si₃N₄ substrate using a photonic Damascene process. Deep-ultraviolet (DUV) stepper lithography is used to pattern optical coupling waveguides and optical microresonators on a 4″ silicon (SI) substrate wafer with a 4-μm thick thermal wet SiO₂ layer (first portion of the embedding layer 40). The pattern is then dry-etched into the SiO₂ layer to form a waveguide preform, followed by a reflow to reduce the preform surface roughness. Stoichiometric Si₃N₄ is deposited by low-pressure chemical vapor deposition (LPCVD) on the patterned substrate, filling the preform and forming the cores of the optical coupling waveguides 21 and the optical microresonators 20. Chemical-mechanical polishing (CMP) is used to remove the excess Si₃N₄ and planarize the wafer top surface. Afterwards, the entire substrate is thermally annealed at 1200° C. to drive out the residual hydrogen contained in the Si₃N₄. An SiO₂ interlayer (second portion of the embedding layer 40) is deposited on the substrate layer 50, followed by densification. The interlayer is then polished to reduce the remaining topography and its thickness is finely controlled. The low surface roughness and long-range uniformity are particularly critical for bonding with lithium niobate-on-insulator (LNOI), i.e. as shown in FIG. 8 a wafer which comprises a thin film of lithium niobate (which then results in the modulation layer 33), on a buried SiO2-layer 34, which is arranged on a Si-carrier 35; that is why this second CMP step is essential. A root-mean-square roughness of 0.4 nm or less as measured by atomic-force microscopy (AFM) on an area of a few square micrometers and a topography of only a few nanometers over several hundred microns are ideal for bonding. Once these criteria for the surface quality are met, an alumina layer is deposited by atomic layer deposition (ALD) on both the donor (LNOI) and acceptor (Damascene) wafers, which are then brought into contact and annealed for hours at 250° C. Next, the LNOI Si-carrier 35 and the buried SiO₂-layer 34 are removed by tetramethylammonium hydroxide and subsequent grinding, and buffered hydrofluoric acid (BHF), respectively. A layer of tungsten (W) is sputtered on the lithium niobate surface, and the electrodes pattern is transferred in this layer via fluoride-based reactive ion etching (RIE). Finally, the lithium niobate is etched by means of argon ion beam etching to open the chip facets areas in order to improve input coupling of the optical radiation. The subsequent chip release is performed in three steps: dry etching of chips boundaries in SiO₂ with fluorine-based chemistry, further etching of Si carrier by the Bosch process known in the art, and backside wafer grinding. Finally, the wafer may be divided into chips for testing.

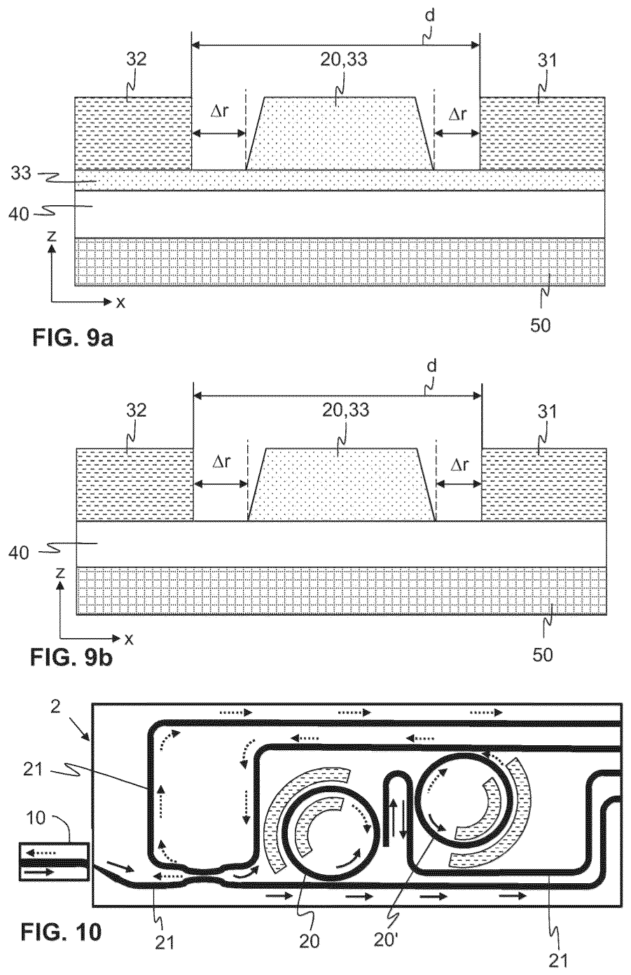

FIG. 9a shows an enlarged excerpt of a sectional view of a photonic modulator chip 2 according to an embodiment of the present invention where the photonic circuit arrangement comprises an optical microresonator 20,33 with a trapezoidal cross-section, which optical microresonator 22,33 itself is part of the modulation element 33, i.e. where the optical microresonator 20,33 consists of a material which exhibits the Pockels effect, e.g. lithium niobate. In the embodiment shown in FIG. 9a, actuation elements 31, 32 in the form of electrodes, preferably made of tungsten, are arranged on a portion of the modulation element 33 which extends as a modulation layer along an embedding layer 40 with respect to a horizontal plane perpendicular to a vertical direction z and which modulation layer is in contact with the optical microresonator 20,33. Here, the embedding layer 40 preferably consists of SiO₂. The photonic modulator chip 2 of this particular embodiment further comprises a substrate layer 50, the embedding layer being arranged on the substrate layer 50 with respect to a vertical direction z, the substrate layer consisting here preferably of Si. Here, the first actuation element 31 and the second actuation element 32 are arranged at a distance d from one another. The first actuation element 31 and the second actuation element 32 are arranged at an offset Δr from the optical microresonator 22, 33 with respect to a radial direction.

FIG. 9b shows an enlarged excerpt of a sectional view of a photonic modulator chip 2 according to an embodiment of the present invention which is identical to the embodiment shown in FIG. 9a except that in the embodiment shown in FIG. 9b, the modulation element 33 consists of the optical microresonator 20, i.e. the modulation element does not comprise a portion which extends as a modulation layer along the embedding layer 40. In the configuration shown here, the first actuation element 31 and the second actuation element 32, which are preferably electrodes as described for FIG. 9a, are arranged directly on the embedding layer 40, which may consist of SiO₂. Upon applying a voltage to the actuation elements 31,32 an electric field builds up, which extends from the first actuation element 31 through a medium (preferably air) surrounding the optical microresonator 20,33 to the second actuation element 32, thereby penetrating the optical microresonator 20,33 and enabling a tuning of the optical feedback wavelength. Compared to configurations where the actuation elements are arranged directly on the modulation element 33 exhibiting the Pockels effect, the configuration shown in FIG. 9b may exhibit a lower modulation efficiency, however, tuning is still possible.

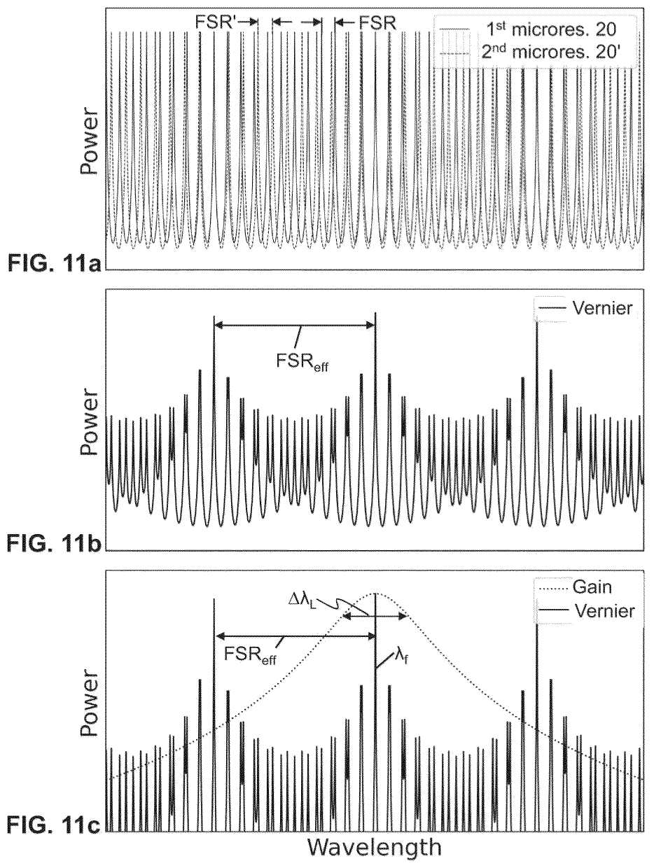

FIG. 10 schematically shows a photonic assembly 1 according to a second embodiment of the present invention. The photonic circuit arrangement of this second embodiment comprises two optical microresonators 20,20′ with differing free-spectral ranges FSR,FSR′, i.e. wherein each of the free-spectral ranges FSR, FSR′ is smaller than the spectral gain bandwidth Δλ_{L} of the active photonic chip. The two optical microresonators 20, 20′ are configured to share multiple common resonance wavelength and are arranged such, that the optical feedback wavelength λ_{f} corresponds to one of the multiple common resonance wavelengths. Such an arrangement creates a so-called “Vernier”-filter, i.e. a filter which suppresses resonance wavelengths that are not shared by both optical microresonators 20,20′. The effect is schematically illustrated in FIG. 11a-c, wherein a power transmission function for each optical microresonator 20, 20′ is shown in FIG. 11a and wherein the resulting Vemier-filter is shown in FIG. 11b. The Vemier-filter has an effective free-spectral range FSR_{aff} which is larger than the free-spectral ranges FSR, FSR′ of the two individual optical microresonators 20, 20′. The optical gain section 11 of the active photonic chip 10 has a spectral gain profile which is schematically plotted in FIG. 11c as a dashed line. The spectral gain bandwidth Δλ_{L} is preferably defined as the full-width-at-half maximum (FWHM) (on a linear scale) or the 3 dB-bandwidth (on a logarithmic scale) of said spectral gain profile. In order to enable a situation where the active photonic chip 10 is able to emit optical radiation 12 at only one optical lasing wavelength λ_{L}, the effective free-spectral range FSR_{eff} is ideally chosen such that only one optical feedback wavelength λ_{f} is situated within the spectral gain bandwidth Δλ_{L}, as shown in FIG. 11c.

As shown in FIG. 10, the photonic circuit arrangement may comprise several optical coupling waveguides 21 of various shapes; three optical coupling waveguides 21 are shown in this particular example and the direction of propagation of the optical radiation 12 coupled from the active photonic chip 10 into the photonic circuit arrangement of the photonic modulator chip 2 is indicated by solid line arrows, while the direction of propagation of the part of the injection radiation 13 that is reflected back from the photonic circuit arrangement to the active photonic chip 10 is indicated by dotted arrows.

FIG. 12 schematically shows a photonic assembly 1 according to a third embodiment of the present invention. The photonic circuit arrangement of this third embodiment comprises a waveguide section 212 configured to form a mirror that reflects a portion of the injection radiation exiting the optical microresonator 20 after having propagated in the optical microresonator 20 in a first direction back (as indicated by solid arrows) into the at least one optical microresonator 20 in a second direction opposite to the first direction (as indicated by dotted arrows). In this example, the waveguide section 212 forming the mirror has a loop-shape with two open ends that are arranged parallel on either side of a straight optical coupling waveguide 21.

FIG. 13 schematically shows a photonic assembly 1 according to a fourth embodiment of the present invention, wherein this forth embodiment represents a combination of the Vernier-filter arrangement comprising two optical microresonators 20,20′ as shown in FIG. with loop-shaped waveguide section 212 configured to form a mirror as shown in FIG. 12.

FIG. 14 schematically shows a photonic assembly 1 according to a fifth embodiment of the present invention. The photonic circuit arrangement of this fifth embodiment comprises a grating element 24 in form of a corrugated waveguide acting as a Bragg reflector, which is actuated using a first actuator 31 and a second actuator 32 extending parallel to one another, wherein the grating element 24 is arranged between the first actuator 31 and the second actuator 32. The corrugated waveguide may have a corrugation period Λ that is chosen such that the optical feedback wavelength λ_{f} falls inside the spectral gain bandwidth of the active photonic chip according to λ_{f}=2·n_{eff}·Λ, where n_{eff} is the effective refractive index of the corrugated waveguide. Applying a voltage between the electrodes 31,32 entails a change of the effective refractive index that entails a tuning of the optical feedback wavelength λ_{f} and the optical lasing wavelength λ_{L}.

Each of the five embodiments described above may be modified without leaving the scope of the present invention. In particular, the photonic circuit arrangement may comprise additional optical microresonators and additional optical coupling waveguides. The photonic circuit arrangement may comprise several Vernier-filter arrangements and several waveguide sections forming mirrors, which may also be combined with one or more grating elements. Furthermore, each embodiment may be realized in a configuration where the photonic circuit arrangement and the modulation element are configured separately (as shown in FIG. 2), or in a configuration where at least a part of the photonic circuit, e.g. at least one optical microresonator, is a part of the modulation element.

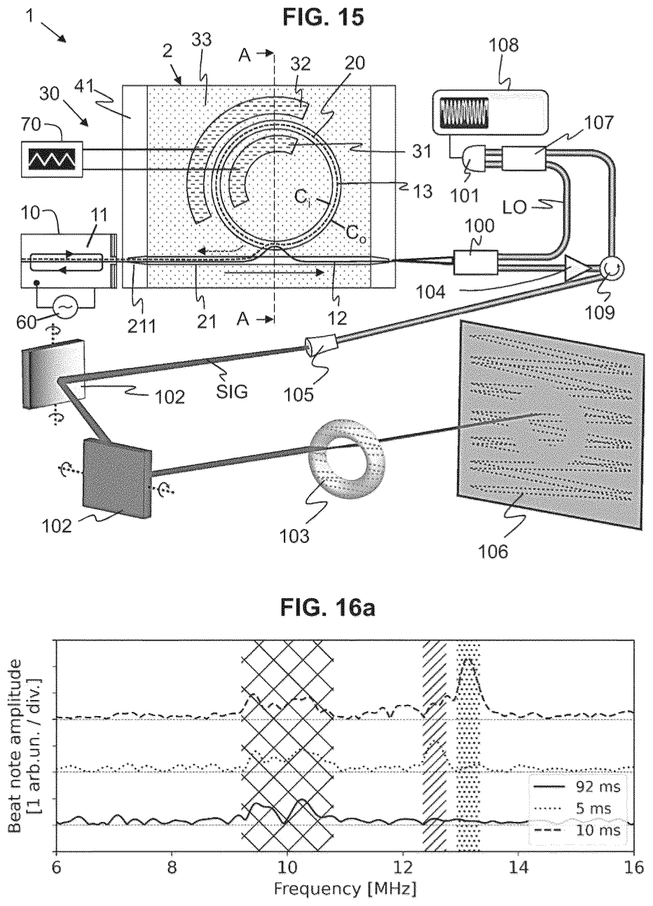

FIG. 15 schematically illustrates how the laser setup shown in FIG. 1 may be used for performing frequency-modulated continuous-wave (FMCW) light detection and ranging (LIDAR). The setup shown in FIG. 15 further comprises an optical splitter 100 and a detector 101. Tuning of the optical lasing wavelength λ_{L} is achieved by locking the optical radiation 12 emitted by the active photonic chip 10 and by applying a voltage generated by the tunable voltage source 70 to the tuning arrangement 30. In a preferred embodiment of the method, the active photonic chip 10 is a DFB laser diode acts, and the value of the laser current supplied to the DFB laser diode by the tunable source driver 60 is kept fixed. The optical feedback wavelength λ_{f} of the photonic circuit arrangement is tuned via the Pockels effect by applying a voltage waveform of an appropriate shape applied to the electrodes 31,32. In a specific embodiment of the method, the optical lasing wavelength λ_{L} is linearly chirped by a triangular voltage ramp with 0.5 V of peak-to-peak amplitude and with a modulation frequency of 100 kHz generated by an arbitrary waveform generator. The triangular voltage ramp is further amplified up to 25 V of the peak-to-peak amplitude by a high-voltage amplifier with 5 MHz bandwidth before being applied to the electrodes 31,32.

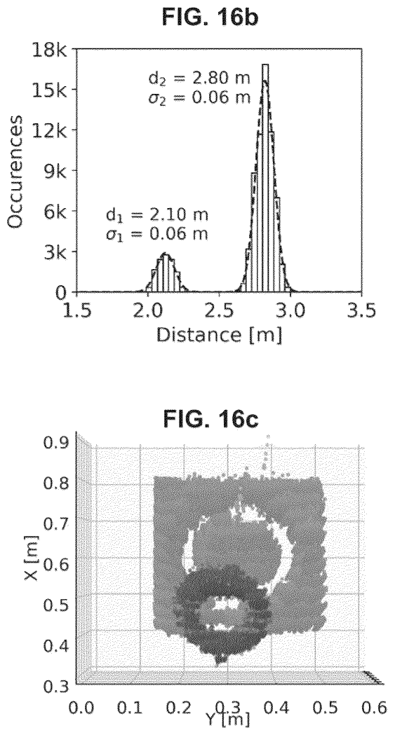

Using a laser setup according to the present invention provides the advantage that no additional processing is needed to linearize the frequency/wavelength ramp of the optical lasing wavelength λ_{L} to enable FMCW LIDAR experiments, since the inherent nonlinearity is low enough. In this specific embodiment of the method, using a laser current of 179 mA applied to the DFB laser diode, a frequency excursion of the optical lasing wavelength λ_{L} of 0.7 GHz is obtained, which is equivalent to a coherent LIDAR spatial resolution of 20 cm. A first portion, preferably 10%, of the optical radiation 12 is split off to act as local oscillator radiation LO using the optical splitter 100. To enable convenient conversion of frequency values into distance values, a fraction, e.g. 5%, of the optical radiation 12 exiting the photonic modulator chip 2 is split off before or after the optical splitter 100 to act as reference radiation and is sent to a reference Mach-Zehnder interferometer (MZI) (not shown explicitly shown in FIG. 15). The length of the MZI may be determined by an independent measurement involving a tunable diode laser scan calibrated by a frequency comb. The length of the MZI used in this example is measured to be 13.18 m. A second portion, preferably 90%, of the optical radiation 12 acting as signal radiation SIG is sent towards a target 103 which at least partially reflects said signal radiation SIG. To obtain a better signal quality, in particular a better signal-to-noise ratio, the signal radiation SIG is amplified by an erbium-doped fiber amplifier 104 (EDFA, Calmar) to an average power of 4 mW and directed through a circulator 109 to a collimator 105 with a 8-mm aperture set to match a target distance range of 3 m between the collimator and the target 103. Mechanical beam-steering is performed using two mirror galvanometers 102 (Thorlabs GVS112) providing two angular degrees of freedom to three-dimensionally scan a space sector in which the target 103 (in this example a polystyrene donut-shaped object) and a wall 106 (here consisting of a plastic material) arranged behind the target 103 are situated. The two mirror galvanometers 102 are actuated by a two-channel arbitrary waveform generator (Keysight) (not explicitly shown in FIG. 15) that transfers linear ramp signals of 3 Hz and 60 Hz with selectable amplitude and offset values to ensure that the target is fully scanned and an area behind the donut on the wall is totally covered by the scanning pattern. A detection signal is obtained by detecting a superposition of the reflected signal radiation SIG and the local oscillator radiation LO together with a superposition of the local oscillator radiation LO and the reference radiation on a balanced photodetector 101. To facilitate the superposition, a 50:50 beam splitter/beam combiner 107 may be used. Here, beat signals resulting from said superpositions are detected as a detection signal by the balanced photodiode 101 and recorded by a digital storage oscilloscope 108 as oscillograms. The oscillograms are then preferably zero padded and subject to a short-time Fourier transform (STFT) with a Blackman-Harris window function having a window size equal to one period of the voltage ramp to obtain a time-frequency maps corresponding to the signal radiation path (i.e. target path) and a time-frequency map corresponding to the reference MZI path. Both time-frequency maps contain 128 k time slices, three of them are shown as examples in FIG. 16a: a first time slice corresponding to a beat signals of the local oscillator radiation LO superposed with the signal radiation SIG reflected from the wall 106 (dashed line) with a signal-to-noise ratio value of 11 dB, a second time slice corresponding to a beat signals of the local oscillator radiation LO superposed with the signal radiation SIG reflected from the donut (target) 103 (dotted line) with a signal-to-noise ratio value of 8 dB, and a third time slice corresponding to a beat signals of the local oscillator radiation LO superposed with the signal radiation SIG reflected from the collimator 105 (solid line) with a signal-to-noise ratio value of 7 dB. Both time-frequency maps may then be used to create a set of frequency values, which frequency values each correspond to a beat signal amplitude peak at a given time instant. This set of frequency values may then be filtered so that only data points with appropriately large beat signal amplitude peaks are considered for further analysis. The frequencies of the data points left after filtering may be corrected to account for a distance to the collimator, so that the retrieved distance values for the target and the wall are given with respect to the collimator aperture position. In a final step, the frequency data may be converted into distance values using the MZI path data as reference.

A resulting distribution of the calculated distance values is plotted as a histogram in FIG. 16b and shows two occurrence peaks representing the donut (smaller peak) and the wall (larger peak). Both peaks are fitted by a double-Gaussian fit, yielding fit parameters that reveal mean distances d₁,d₂ and associated standard deviations σ₁,σ₂, wherein the latter represent a resolution measure. By transforming the spherical coordinates of the angular degrees of freedom evaluated from the voltage profile applied to the mirror galvanometers 102 into Cartesian components, it is possible to build a point cloud, wherein the data points in the point cloud show the target 103, as can be seen in FIG. 16c. The data for the point cloud in this example was collected within a time interval of 1.3 ms.

### LIST OF REFERENCE SIGNS

1 photonic assembly
2 photonic modulator chip
10 active photonic chip
11 gain section
12 optical radiation
13 injection radiation
24 grating element
20,20′ optical microresonator combiner
21 optical coupling waveguide
22 facet
211 input section
31 first actuation element
32 second actuation element
33 modulation element
34 buried SiO₂-layer
35 Si-carrier
40 embedding layer
41 portion of the embedding layer d distance
50 substrate layer
60 tunable source driver
70 tunable voltage source
80 lensed fiber
81 50:50 beam splitter/beam combiner
82 reference continuous-wave laser source
83 photodiode
84 radiofrequency analyzer
100 optical splitter
101 detector
102 mirror galvanometer
103 target
104 erbium-doped fiber amplifier
105 collimator
106 wall
107 50:50 beam splitter/beam
108 digital storage oscilloscope
109 circulator
Δλ_{L} spectral gain bandwidth
λₘ resonance wavelength
λ_{f} optical feedback wavelength
λ_{L} optical lasing wavelength
fₑ heterodyne beat note
z vertical direction
FSR,FSR′ free-spectral range
FSR_{eff} effective free-spectral range
g distance
Δr offset with respect to a radial direction
Δz offset with respect to a vertical direction
Ci inner circumference
Co outer circumference
LO local oscillator radiation
SIG signal radiation

1. A photonic assembly comprising:
an active photonic chip comprising an optical gain section defining a spectral gain bandwidth, wherein the active photonic chip is configured to emit optical radiation within said spectral gain bandwidth;
a photonic modulator chip comprising a photonic circuit arrangement,
wherein the active photonic chip and the photonic modulator chip are optically coupled such, that at least a part of the optical radiation being emitted from the active photonic chip is injected into the photonic circuit arrangement, whereby injection radiation at an optical feedback wavelength is generated, and
wherein the active photonic chip and the photonic modulator chip are further optically coupled such, that at least a part of the injection radiation is reflected back from the photonic circuit arrangement to the active photonic chip such, that the optical feedback wavelength defines at least one optical lasing wavelength at which the optical radiation is emitted by the active photonic chip, and
a tuning arrangement comprising a modulation element exhibiting the Pockels effect, wherein the modulation element is monolithically integrated in the photonic modulator chip and has a thickness of 10 micrometers or less, with respect to a vertical direction defined by the photonic assembly,
and wherein the modulation element is arranged such, that an actuation of the modulation element tunes the optical feedback wavelength via the Pockels effect, such, that a tuning of the optical feedback wavelength entails a tuning of the optical lasing wavelength.

2. The photonic assembly of claim 1, wherein the photonic circuit arrangement and the modulation element are configured separately from one another.

3. The photonic assembly of claim 2, wherein the photonic modulator chip comprises at least an embedding layer, and wherein at least one of:
the photonic circuit arrangement is at least partially embedded in the embedding layer,
the modulation element extends as a modulation layer at least partially along the embedding layer with respect to a horizontal plane being perpendicular to the vertical direction, or
the photonic modulator chip further comprises at least a substrate layer.

4. The photonic assembly of claim 3, wherein at least one of:
the photonic circuit arrangement comprises or consists of at least one of: silicon nitride or silicon, and/or
the substrate layer comprises or consists of silicon,
the embedding layer comprises or consists of silicon dioxide, or
the modulation element comprises or consists of at least one of: lithium niobate, lithium tantalate, or barium titanate.

5. The photonic assembly of claim 1, wherein the photonic circuit arrangement comprises a grating element.

6. The photonic assembly of claim 1, wherein the photonic circuit arrangement comprises at least one coupling waveguide and at least one optical microresonator, and wherein at least one of:
the at least one optical microresonator has a quality factor larger than 10⁶,
the at least one optical microresonator and the least one coupling waveguide are arranged in a common plane perpendicular to the vertical direction, or
the least one optical coupling waveguide is configured to guide the optical radiation emitted by the active photonic chip and to couple a portion of said optical radiation into the at least one optical microresonator, thereby generating the injection radiation at the optical feedback wavelength.

7. The photonic assembly of claim 6,
wherein the at least one coupling waveguide comprises an input section, and wherein at least one of:
the active photonic chip is being butt-coupled to said input section, or
a portion of the embedding layer is not covered by the modulation layer and wherein the input section of the at least one coupling waveguide is arranged within said portion of the embedding layer.

8. The photonic assembly of claim 6, wherein the at least one optical microresonator has multiple resonance wavelengths spaced by a free-spectral range, wherein the free-spectral range is larger than the spectral gain bandwidth of the active photonic chip.

9. The photonic assembly according to claim 1, wherein the photonic circuit arrangement comprises at least two optical microresonators with differing free-spectral ranges, and wherein at least one of:
each of the free-spectral ranges is smaller than the spectral gain bandwidth of the active photonic chip,
the at least two optical microresonators are configured to share at least one common resonance wavelength, or
the at least two optical microresonators are arranged such, that the optical feedback wavelength corresponds to the at least one common resonance wavelength.

10. The photonic assembly of claim 6, wherein the photonic circuit arrangement further comprises a waveguide section configured to form a mirror that reflects a portion of the injection radiation exiting the at least one optical microresonator after having propagated in the at least one optical microresonator in a first direction back into the at least one optical microresonator in a second direction opposite to the first direction.

11. The photonic assembly according to claim 1, wherein the tuning arrangement comprises at least a first actuation element and a second actuation element, wherein the first actuation element and the second actuation element are configured to actuate the modulation element, and wherein at least one of:
the first actuation element and the second actuation element are electrodes, or
the first actuation element and the second actuation element are arranged at a distance from one another.

12. The photonic assembly according to claim 11,
wherein the photonic circuit arrangement comprises at least one optical microresonator, and
wherein at least one of the first actuation element or the second actuation element are arranged at least one of: at an offset from the at least one optical microresonator with respect to a radial direction or at an offset with respect to the vertical direction running perpendicularly to the radial direction.

13. The photonic assembly according to claim 12, wherein the at least one optical microresonator defines an inner circumference and an outer circumference, and
wherein the first actuation element extends along the inner circumference of the at least one optical microresonator over a length that amounts to half of a length of the inner circumference of the at least one optical microresonator or less, and
wherein the second actuation element extends along the outer circumference of the at least one optical microresonator over a length that amounts to half of a length of the outer circumference of the at least one optical microresonator or less.

14. The photonic assembly according to claim 1, wherein the active photonic chip is a distributed-feedback laser diode or a Fabry-Perot laser diode or a reflective semiconductor amplifier.

15. A laser setup comprising:
the photonic assembly of claim 1,
a tunable source driver configured to drive the active photonic chip, and
a tunable voltage source configured to provide a tunable voltage to the tuning arrangement.

16. A method for performing frequency-modulated continuous-wave light detection and ranging using the setup of claim 15, wherein the setup further comprises an optical splitter and a detector, and wherein the method comprises:
tuning the optical lasing wavelength of the optical radiation by applying a voltage generated by the tunable voltage source to the tuning arrangement;
splitting off a first portion of the optical radiation to act as local oscillator radiation using the optical splitter;
sending a second portion of the optical radiation being split of by the optical splitter and acting as signal radiation towards a target which at least partially reflects said signal radiation;
obtaining a detection signal by detecting a superposition of the reflected signal radiation and the local oscillator radiation by the detector, and
retrieving a ranging parameter from the detection signal.

17. The photonic assembly of claim 1, wherein the modulation element has a thickness of at least one of: 1 micrometer or less or 200-700 nanometers, with respect to the vertical direction defined by the photonic assembly.

18. The photonic assembly of claim 3, wherein the embedding layer is arranged on the substrate layer with respect to the vertical direction.

19. The photonic assembly of claim 6, wherein the at least one optical microresonator has at least one of:
a circular shape or a race-track shape, or
a rectangular or a trapezoidal cross-section.

20. The photonic assembly according to claim 11, wherein the electrodes comprise or consist of at least one of: tungsten or niobium.
